(19) United States
(12) Patent Application Publication
(10) Pub. No.: US 2026/0186534 A1
(43) Pub. Date: Jul. 2, 2026

(54) CURVED DISPLAY APPARATUS

(71) Applicant: AUO Corporation, Hsinchu City (TW)

(72) Inventors: Chih-Tsung Lee, Hsinchu City (TW); Ming-Hsuan Yu, Hsinchu City (TW); Pei-Chia Wu, Hsinchu City (TW); Chih-Yu Yu, Hsinchu City (TW); Yen-Huei Lai, Hsinchu City (TW); Wan-Tsang Wang, Hsinchu City (TW)

(73) Assignee: AUO Corporation, Hsinchu City (TW)

(21) Appl. No.: 19/248,490

(22) Filed: Jun. 25, 2025

(30) Foreign Application Priority Data
Dec. 31, 2024 (TW) 113151648

(51) Int. Cl. G06F 1/16; H05K 1/18

(52) U.S. Cl. CPC G06F 1/1652; H05K 1/189

(57) ABSTRACT

A curved display apparatus includes a curved carrier, a stretchable display module, and a first fixing member. The stretchable display module includes a stretchable display panel and a flexible electronic component. The stretchable display panel is arranged to fit on the curved surface of the curved carrier. The stretchable display panel has a first edge and a second edge opposite to each other. A length of the second edge is greater than a length of the first edge. A bonding zone of the stretchable display panel has the first edge. The flexible electronic component is bonded to the bonding zone of the stretchable display panel. The flexible electronic component has a fixation portion located outside the stretchable display panel. The fixing member is matched with the fixation portion of the flexible electronic component to fix the stretchable display module onto the curved carrier.

### CROSS-REFERENCE TO RELATED APPLICATION

This application claims the priority benefit of Taiwan application serial no. 113151648, filed on Dec. 31, 2024. The entirety of the above-mentioned patent application is hereby incorporated by reference herein and made a part of this specification.

### BACKGROUND

### Technical Field

The disclosure relates to a curved display apparatus.

### Description of Related Art

With the rapid development of electronic technology, new electronic products are constantly being launched. In order to enable electronic products to be applied in various different fields, the characteristics of stretchability, thinness, and unrestricted appearance are gradually receiving attention. That is, electronic products are increasingly being required to have different appearances according to different application methods and application environments. Therefore, electronic products need to be stretchable. However, when electronic products are in a stretched state, problems such as bonding zone damage and irregular warping may occur due to stress.

### SUMMARY

The disclosure provides a curved display apparatus capable of improving the problem of irregular warping.

The disclosure provides a curved display apparatus includes a curved carrier, a stretchable display module, and a first fixing member. The stretchable display module includes a stretchable display panel and a flexible electronic component. The stretchable display panel is arranged to fit substantially on the curved surface of the curved carrier. The stretchable display panel has a first edge and a second edge opposite to each other. A length of the second edge is greater than a length of the first edge. The stretchable display panel has a bonding zone. The bonding zone has the first edge of the stretchable display panel. The flexible electronic component is bonded to the bonding zone of the stretchable display panel. The flexible electronic component has a fixation portion located outside the stretchable display panel. The fixing member is matched with the fixation portion of the flexible electronic component to fix the stretchable display module onto the curved carrier.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic three-dimensional view of a curved display apparatus according to an embodiment of the disclosure.

FIG. 2 is a schematic three-dimensional view of a portion of the curved display apparatus according to an embodiment of the disclosure.

FIG. 3 illustrates an application scenario of the curved display apparatus according to an embodiment of the disclosure.

FIG. 4 is a schematic front view of the curved display apparatus according to an embodiment of the disclosure.

FIG. 5 is a schematic cross-sectional view of the curved display apparatus according to an embodiment of the disclosure.

FIG. 6 is a schematic cross-sectional view of a portion of the curved display apparatus according to an embodiment of the disclosure.

FIG. 7 is a schematic cross-sectional view of a portion of the curved display apparatus according to another embodiment of the disclosure.

FIG. 8 to FIG. 13 are schematic side views of a stretchable display module and various curved carriers.

FIG. 14 to FIG. 26 are schematic top views of the curved display apparatus installed in a transportation vehicle.

FIG. 27 is a schematic three-dimensional view of the curved display apparatus installed in the transportation vehicle according to an embodiment of the disclosure.

FIG. 28 is a schematic three-dimensional view of the curved display apparatus installed in the transportation vehicle according to an embodiment of the disclosure.

FIG. 29 is a schematic three-dimensional view of the curved display apparatus installed on an armrest according to an embodiment of the disclosure.

### DESCRIPTION OF THE EMBODIMENTS

Descriptions of the disclosure are given with reference to the exemplary embodiments illustrated by the accompanying drawings. Wherever possible, the same reference numerals are used in the drawings and the description to refer to the same or like parts.

It should be understood that when an element such as a layer, film, region or substrate is referred to as being “on” or “connected to” another element, it means that the element is directly on or connected to the another element, or an intervening element may be provided therebetween. In contrast, when an element is referred to as being “directly on” or “directly connected to” another element, there are no intervening elements present. As used herein, the term “connected” may refer to physical connection and/or electrical connection. Further, the “electrical connection” or “coupling” may be that other elements are provided between two elements.

The terms used herein such as “about”, “approximate”, or “substantial” include a related value and an average within an acceptable deviation range of specific values determined by those with ordinary skills in the art with consideration of discussed measurement and a specific number of errors related to the measurement (i.e., a limitation of a measurement system). For example, “about” may mean within one or more standard deviations, or within, for example, ±30%, ±20%, ±15%, ±10%, and ±5% of the stated value. Moreover, a relatively acceptable range of deviation or standard deviation may be chosen for the term “about”, “approximately”, or “substantially” as used herein based on optical properties, etching properties or other properties, instead of applying one standard deviation across all the properties.

Unless otherwise defined, all terms (including technical and scientific terms) used herein have the same meaning as commonly understood by a person having ordinary skill in the art. It will be further understood that, terms such as those defined in commonly used dictionaries should be interpreted as having a meaning that is consistent with their meaning in the context of the related art, and these terms are not to be construed in an idealized or excessively formal sense unless explicitly defined as such herein.

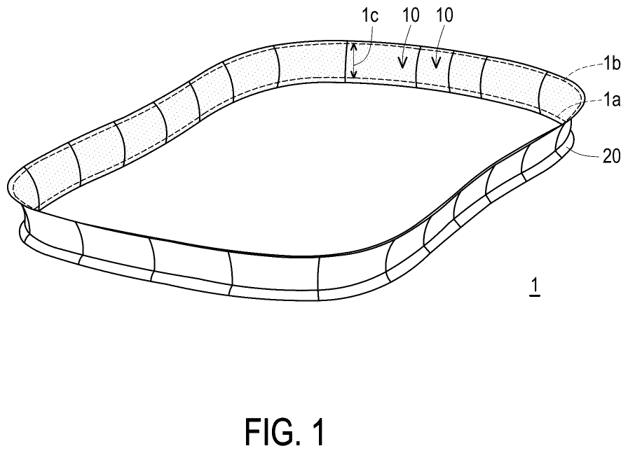

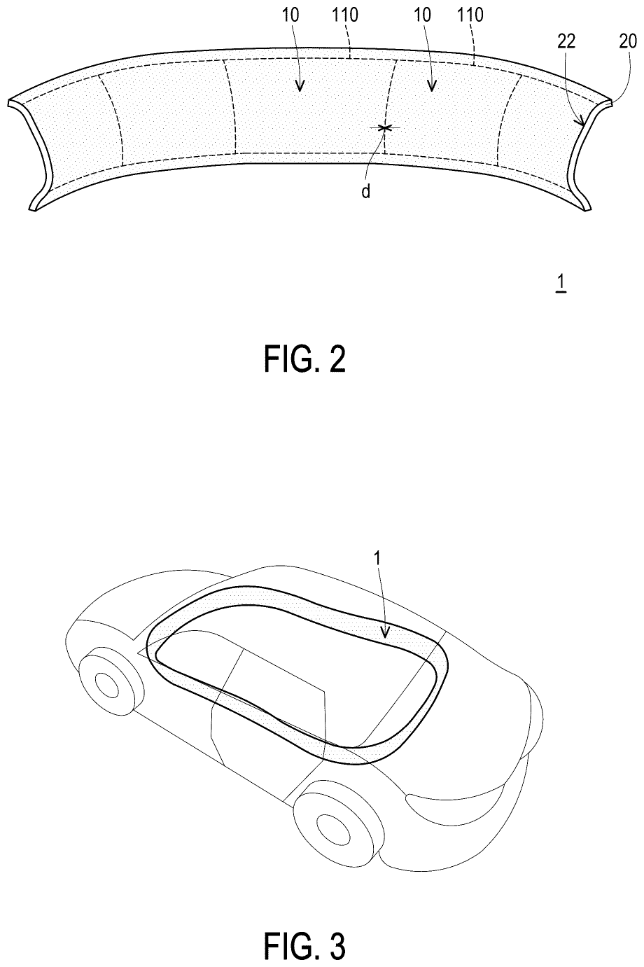

FIG. 1 is a schematic three-dimensional view of a curved display apparatus according to an embodiment of the disclosure. FIG. 2 is a schematic three-dimensional view of a portion of the curved display apparatus according to an embodiment of the disclosure. FIG. 3 illustrates an application scenario of the curved display apparatus according to an embodiment of the disclosure.

Referring to FIG. 1 and FIG. 2, a curved display apparatus 1 includes a curved carrier 20 having a curved surface 22 and at least one stretchable display module 10 installed on the curved carrier 20. Referring to FIG. 1, FIG. 2, and FIG. 3, for instance, in some embodiments, the curved display apparatus 1 may be applied inside a transportation vehicle and is used as a cabin display. Herein, the curved display apparatus 1 may selectively include a plurality of stretchable display modules 10. However, the disclosure is not limited thereto, the number of the stretchable display modules 10 included in the curved display apparatus 1 depends on the actual application needs, which is not limited by the disclosure. In another embodiment that is not shown, the number of the stretchable display modules 10 included in the curved display apparatus 1 may also be one. In addition, the disclosure does not limit the curved display apparatus 1 to be used only as a cabin display. The curved display apparatus 1 may also be a display installed in a local region inside the transportation vehicle or applied in scenarios outside the transportation vehicle.

Referring to FIG. 1 and FIG. 2, each stretchable display module 10 includes a stretchable display panel 110. In some embodiments, the curved display apparatus 1 includes a stretched stretchable display panel 110 and has a shape curve 1a. A length of the shape curve 1a is A, A=n·H+(n+1)·d, where n is a positive integer, H is a horizontal direction length of the stretchable display panel 110 before being stretched, d is a width of a gap between two adjacent stretchable display panels 110, and d≥0. In some embodiments, the curved display apparatus 1 also has a shape curve 1b, the shape curve 1b is opposite to the shape curve 1a, a length of the shape curve 1a is B, and A<B<1.5 A. In some embodiments, the curved display apparatus 1 also has a shape curve 1c, the shape curve 1c intersects with the shape curves 1a and 1b. The shape curve 1c has a length C, and C<1.5Vₒ, where Vₒ is a vertical direction length of the stretchable display panel 110 before being stretched.

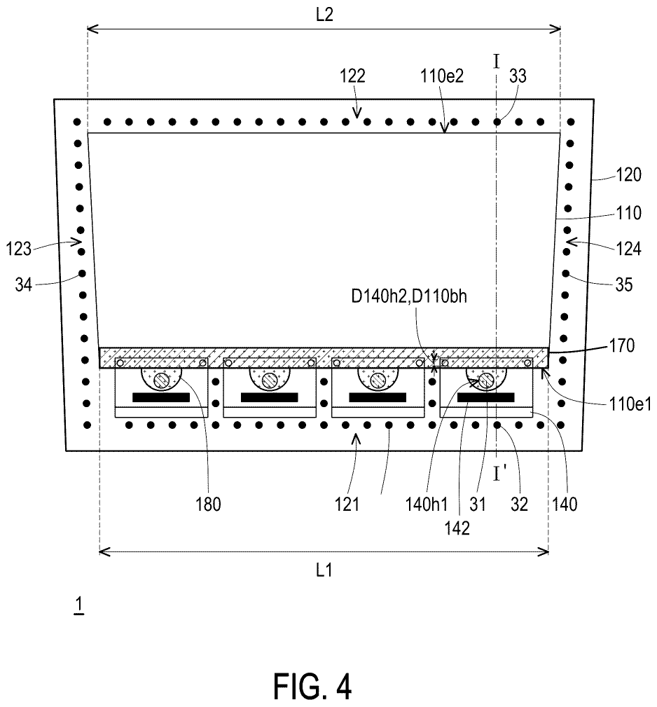

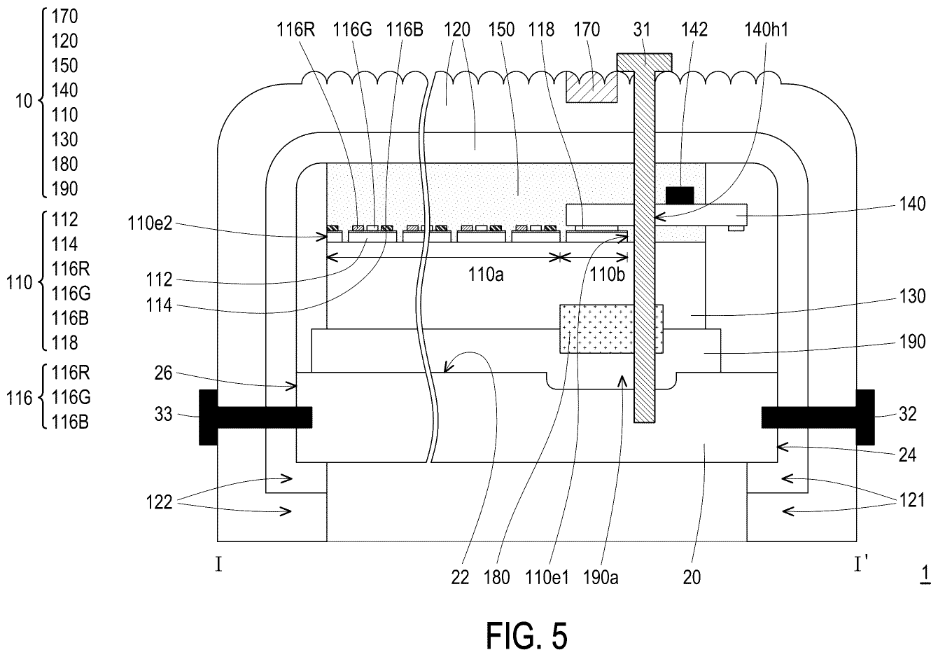

FIG. 4 is a schematic front view of the curved display apparatus according to an embodiment of the disclosure. FIG. 5 is a schematic cross-sectional view of the curved display apparatus according to an embodiment of the disclosure. FIG. 5 corresponds to a cross-sectional line I-I′ of FIG. 4.

Referring to FIG. 4 and FIG. 5, the stretchable display module 10 includes the stretchable display panel 110. The stretchable display panel 110 after being stretched may be arranged to fit substantially on the curved surface 22 of the curved carrier 20. The stretchable display panel 110 that is stretched and installed on the curved carrier 20 has a first edge 110e1 and a second edge 110e2 opposite to each other, and a length L2 of the second edge 110e2 is greater than a length L1 of the first edge 110e1.

In some embodiments, the stretchable display panel 110 includes a stretchable substrate 112, a driving circuit layer 114 arranged on the stretchable substrate 112, a plurality of pixel structures 116 electrically connected to the driving circuit layer 114, and a pad 118 electrically connected to the driving circuit layer 114. The stretchable display panel 110 has a display zone 110a and a bonding zone 110b. The pixel structures 116 are located in the display zone 110a. The pad 118 is located in the bonding zone 110b. The first edge 110e1 is the edge close to the pad 118, while the second edge 110e2 is the edge away from the pad 118. In some embodiments, each pixel structure 116 may include a plurality of light-emitting components 116R, 116G, and 116B. For instance, in some embodiments, the light-emitting components 116R, 116G, and 116B may be micro light-emitting diodes (μLED), but the disclosure is not limited thereto.

Referring to FIG. 4 and FIG. 5, the stretchable display module 10 further includes a flexible electronic component 140. The bonding zone 110b of the stretchable display panel 110 has the first edge 110e1 of the stretchable display panel 110. The flexible electronic component 140 is bonded to the bonding zone 110b of the stretchable display panel 110. Specifically, the flexible electronic component 140 is bonded to the pad 118 of the stretchable display panel 110. For instance, in some embodiments, the flexible electronic component 140 may include a chip 142, where the chip 142 may be bonded to the stretchable display panel 110 via a chip on film (COF) packaging. However, the disclosure is not limited thereto. In other embodiments, the flexible electronic component 140 may also be other types of flexible components. The flexible electronic component 140 has a fixation portion 140h1 located outside the stretchable display panel 110. In some embodiments, the fixation portion 140h1 of the flexible electronic component 140 is, for example, a through hole. In some embodiments, the fixation portion 140h1 of the flexible electronic component 140 may selectively be arranged between the pad 118 of the stretchable display panel 110 and the chip 142 of the flexible electronic component 140, but the disclosure is not limited thereto.

Referring to FIG. 4 and FIG. 5, the curved display apparatus 1 also includes a first fixing member 31. The first fixing member 31 is matched with the fixation portion 140h1 of the flexible electronic component 140, so as to fix the stretchable display module 10 onto the curved carrier 20. Through the matching of the first fixing member 31 with the fixation portion 140h1 of the flexible electronic component 140, the problem of the bonding zone 110b being easily damaged may be improved.

In some embodiments, the stretchable display module 10 further includes a decorative component layer 120 arranged on the stretchable display panel 110. The first fixing member 31 may pass through the decorative component layer 120 and the fixation portion 140h1 of the flexible electronic component 140, and a portion of the first fixing member 31 may be arranged in the curved carrier 20. For instance, in some embodiments, the first fixing member 31 may be a fixing pin, a nail, a seam, or a screw, but the disclosure is not limited thereto. In some embodiments, the first fixing member 31 is located between the bonding zone 110b of the stretchable display panel 110 and the chip 142 of the flexible electronic component 140, but the disclosure is not limited thereto.

Referring to FIG. 5, in some embodiments, the stretchable display module 10 further includes an upper hard board layer 170, a carrier board layer 130, and a lower hard board layer 180. The upper hard board layer 170 is embedded or buried in the decorative component layer 120 and overlaps the bonding zone 110b of the stretchable display panel 110. The stretchable display panel 110 is arranged on the carrier board layer 130. The stretchable display panel 110 is located between the decorative component layer 120 and the carrier board layer 130. The carrier board layer 130 is located between the stretchable display panel 110 and the lower hard board layer 180. The lower hard board layer 180 overlaps the bonding zone 110b of the stretchable display panel 110. The upper hard board layer 170 and the lower hard board layer 180 overlap at least at the location of the pad 118. Hardness of the upper hard board layer 170 and the lower hard board layer 180 is greater than hardness of other film layers of the stretchable display panel 110 (for example but not limited to the decorative component layer 120, the carrier board layer 130, the stretchable display panel 110, etc.). In some embodiments, the first fixing member 31 may pass through at least one of the upper hard board layer 170 and the lower hard board layer 180.

In some embodiments, the stretchable display module 10 further includes a protection layer 150. The protection layer 150 is arranged on the carrier board layer 130 and covers the stretchable display panel 110 and a portion of the flexible electronic component 140. The protection layer 150 is located between the decorative component layer 120 and the stretchable display panel 110 as well as between the decorative component layer 120 and the flexible electronic component 140. In some embodiments, the protection layer 150 may cover the chip 142 of the flexible electronic component 140, but the disclosure is not limited thereto.

In some embodiments, the stretchable display module 10 further includes a sensing layer 190. The carrier board layer 130 is located between the stretchable display panel 110 and the sensing layer 190. In some embodiments, the sensing layer 190 is, for example, a touch sensing layer, but the disclosure is not limited thereto. In some embodiments, the first fixing member 31 may further pass through the protection layer 150 and the sensing layer 190.

In some embodiments, a portion of the lower hard board layer 180 may be embedded in the carrier board layer 130, and a portion of the lower hard board layer 180 may protrude from the carrier board layer 130. The sensing layer 190 covers the portion of the lower hard board layer 180 that protrudes from the carrier board layer 130 to form a protrusion portion 190a. The protrusion portion 190a of the sensing layer 190 overlaps the lower hard board layer 180. In some embodiments, the protrusion portion 190a may be engaged with the curved carrier 20 for limiting the position of the curved carrier 20. In some embodiments, the first fixing member 31 may pass through the protrusion portion 190a of the sensing layer 190, but the disclosure is not limited thereto.

Referring to FIG. 4 and FIG. 5, in some embodiments, the decorative component layer 120 has a first extension portion 121 crossing over the first edge 110e1 of the stretchable display panel 110 and extending outside the stretchable display panel 110. The curved display apparatus 1 further includes a second fixing member 32 connecting the first extension portion 121 of the decorative component layer 120 and the curved carrier 20. Specifically, in some embodiments, the curved carrier 20 further has a first surface 24 connected to the curved surface 22. The first extension portion 121 of the decorative component layer 120 extends curvedly from above the stretchable display panel 110 to the first surface 24 of the curved carrier 20. The second fixing member 32 connects the first extension portion 121 of the decorative component layer 120 and the first surface 24 of the curved carrier 20.

In some embodiments, the second fixing member 32 may pass through the first extension portion 121 of the decorative component layer 120 and is inserted into the curved carrier 20. For instance, in some embodiments, the first fixing member 31 may be a screw, a nail, or a fixing pin, etc., but the disclosure is not limited thereto. In some embodiments, the second fixing member 32 may pass through the first extension portion 121 of the decorative component layer 120 and pass through the curved carrier 20. For instance, in some embodiments, the first fixing member 31 may be a seam, but the disclosure is not limited thereto.

Referring to FIG. 4 and FIG. 5, in some embodiments, the decorative component layer 120 further has a second extension portion 122 crossing over the second edge 110e2 of the stretchable display panel 110 and extending outside the stretchable display panel 110. The curved display apparatus 1 further includes a third fixing member 33 connecting the second extension portion 122 of the decorative component layer 120 and the curved carrier 20. Specifically, in some embodiments, the curved carrier 20 further has a second surface 26 connected to the curved surface 22 and is opposite to the first surface 24. The second extension portion 122 of the decorative component layer 120 may extend curvedly from above the stretchable display panel 110 to the second surface 26 of the curved carrier 20. The third fixing member 33 may connect the second extension portion 122 of the decorative component layer 120 and the second surface 26 of the curved carrier 20.

In some embodiments, the decorative component layer 120 further has a third extension portion 123 and a fourth extension portion 124. The third extension portion 123 extends beyond the stretchable display panel 110 and is connected between the first extension portion 121 and the second extension portion 122. The fourth extension portion 124 extends beyond the stretchable display panel 110, is connected between the first extension portion 121 and the second extension portion 122, and is opposite to the third extension portion 123. In some embodiments, the curved display apparatus 1 further includes a fourth fixing member 34 and a fifth fixing member 35. The fourth fixing member 34 connects the third extension portion 123 of the decorative component layer 120 and the curved carrier 20. The fifth fixing member 35 connects the fourth extension portion 124 of the decorative component layer 120 and the curved carrier 20. For instance, in some embodiments, the fourth fixing member 34 and the fifth fixing member 35 may be screws, nails, fixing pins, or seams, etc., but the disclosure is not limited thereto.

In some embodiments, during a manufacturing process of the curved display apparatus 1, the first extension portion 121 of the decorative component layer 120, which is located on the side where the flexible electronic component 140 is positioned, may first be fixed onto the curved carrier 20 through the first fixing member 31 and the second fixing member 32. Next, the second extension portion 122 of the decorative component layer 120, which is located on the opposite side of the flexible electronic component 140, may be fixed onto the curved carrier 20 through the third fixing member 33. Next, the third extension portion 123, which is located on one of the left and right sides of the flexible electronic component 140, may be fixed onto the curved carrier 20 through the fourth fixing member 34. Finally, the fourth extension portion 124, which is located on the other of the left and right sides of the flexible electronic component 140, may be fixed onto the curved carrier 20 through the fifth fixing member 35.

It should be noted that the reference numerals and a part of the contents in the previous embodiment are used in the following embodiments, in which identical reference numerals indicate identical or similar components, and repeated description of the same technical contents is omitted. Please refer to the description of the previous embodiments for the omitted content, which will not be repeated hereinafter.

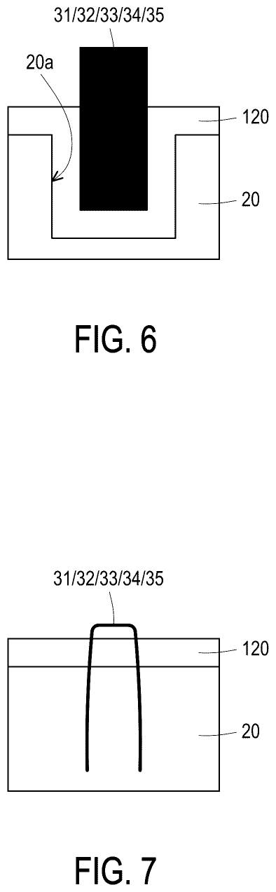

FIG. 6 is a schematic cross-sectional view of a portion of the curved display apparatus according to an embodiment of the disclosure. Referring to FIG. 6, in this embodiment, the first fixing member 31/second fixing member 32/third fixing member 33/fourth fixing member 34/fifth fixing member 35 may fix the decorative component layer 120 onto the curved carrier 20 through compression. Specifically, in this embodiment, the first fixing member 31/second fixing member 32/third fixing member 33/fourth fixing member 34/fifth fixing member 35 may a be fixing pin. The curved carrier 20 may have a fixing hole 20a, and the first fixing member 31/second fixing member 32/third fixing member 33/fourth fixing member 34/fifth fixing member 35 may press the decorative component layer 120 into the fixing hole 20a of the curved carrier 20 to fix the decorative component layer 120 onto the curved carrier 20.

FIG. 7 is a schematic cross-sectional view of a portion of the curved display apparatus according to another embodiment of the disclosure. Referring to FIG. 7, in this embodiment, the first fixing member 31/second fixing member 32/third fixing member 33/fourth fixing member 34/fifth fixing member 35 may fix the decorative component layer 120 onto the curved carrier 20 through piercing.

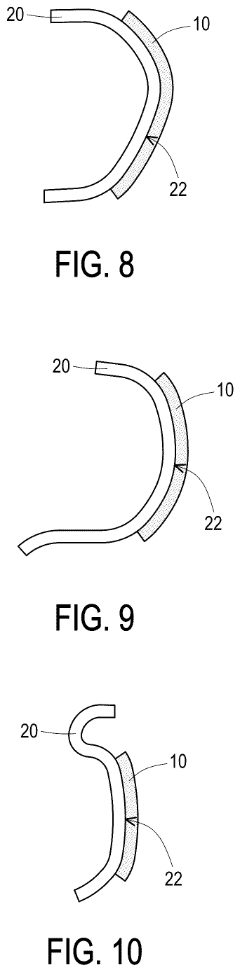

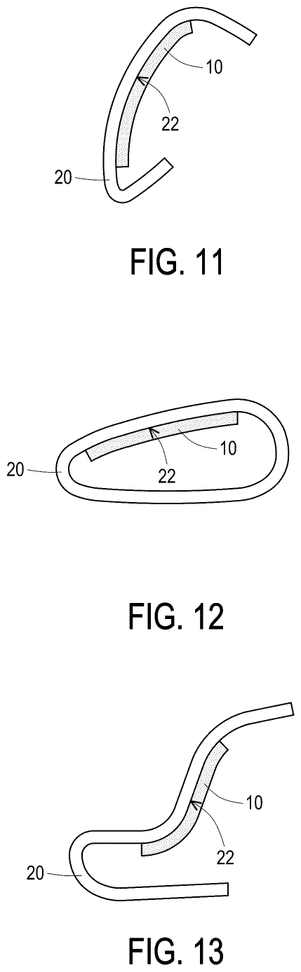

FIG. 8 to FIG. 13 are schematic side views of a stretchable display module and various curved carriers. Referring to FIG. 8, FIG. 9, and FIG. 10, in some embodiments, the curved surface 22 of the curved carrier 20 may be a convex surface with any degree of protrusion, and the stretchable display module 10 may be installed on the convex surface. Referring to FIG. 11 and FIG. 12, in some embodiments, the curved surface 22 of the curved carrier 20 may be a concave surface with any degree of depression, and the stretchable display module 10 may be installed on the concave surface. Referring to FIG. 13, in some embodiments, the curved surface 22 of the curved carrier 20 may be a composite surface including both concave and convex surfaces, and the stretchable display module 10 may be installed on the composite surface.

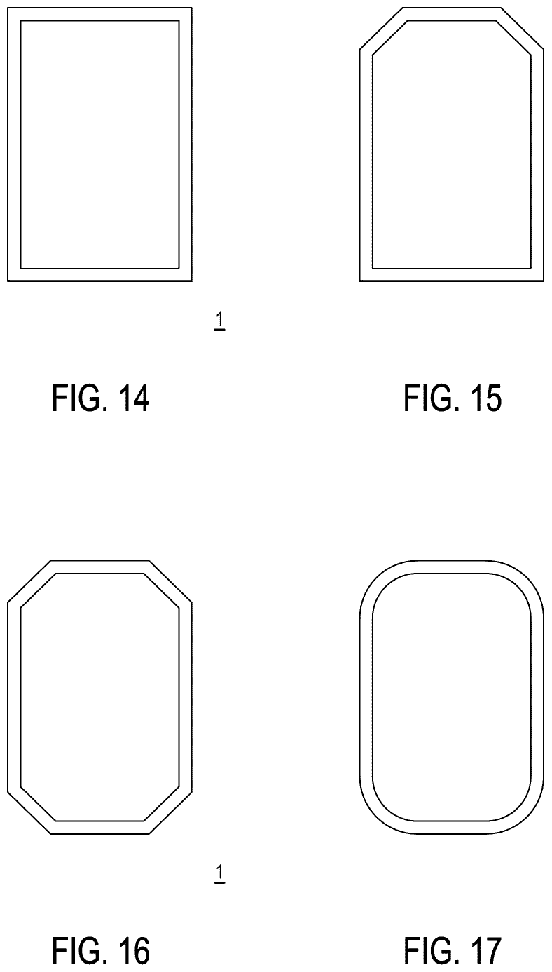

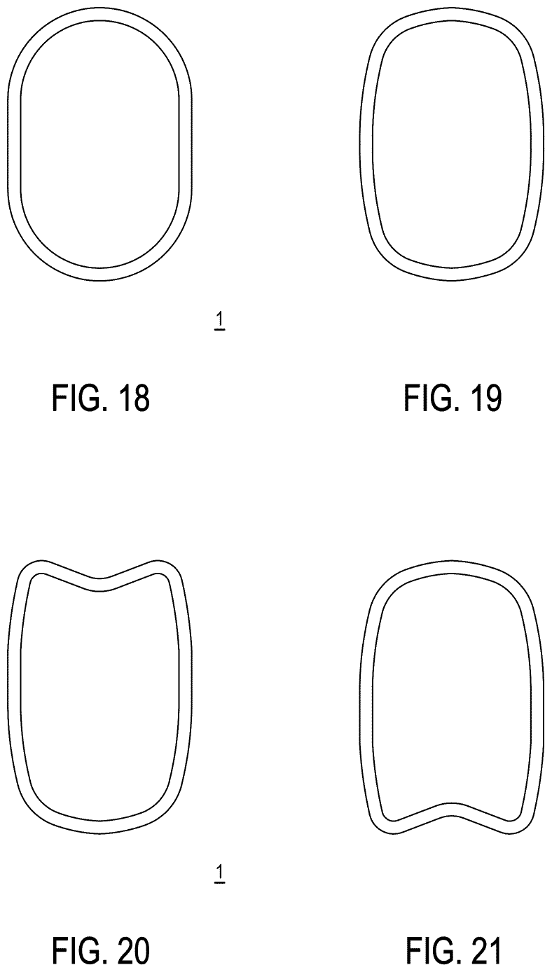

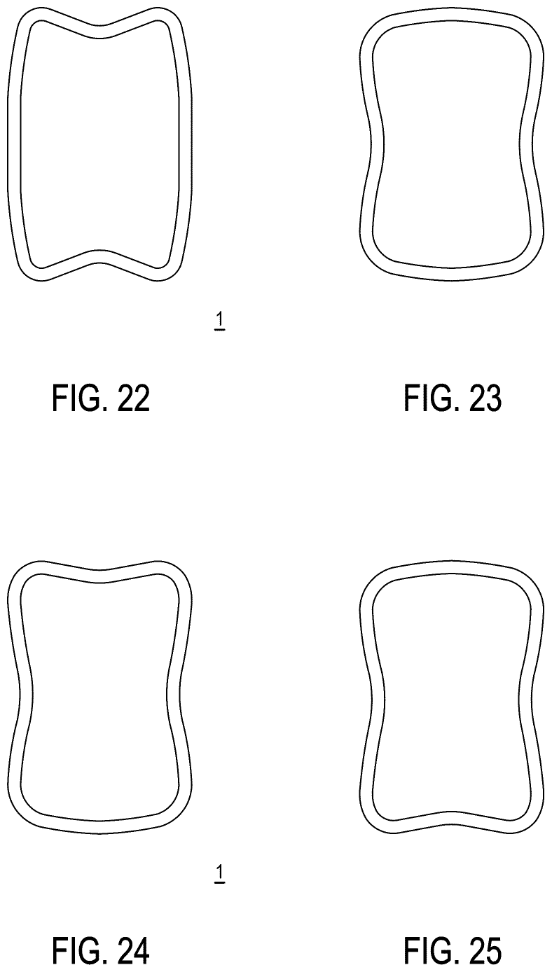

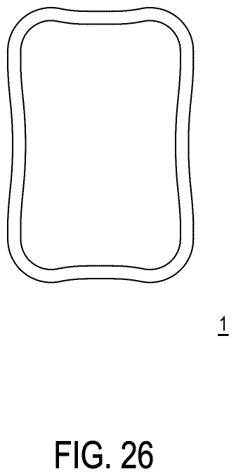

FIG. 14 to FIG. 26 are schematic top views of the curved display apparatus installed in a transportation vehicle. Referring to FIG. 14 to FIG. 26, in some embodiments, the curved display apparatus 1 may have any shape, for example but not limited to the shapes shown in FIG. 14 to FIG. 26.

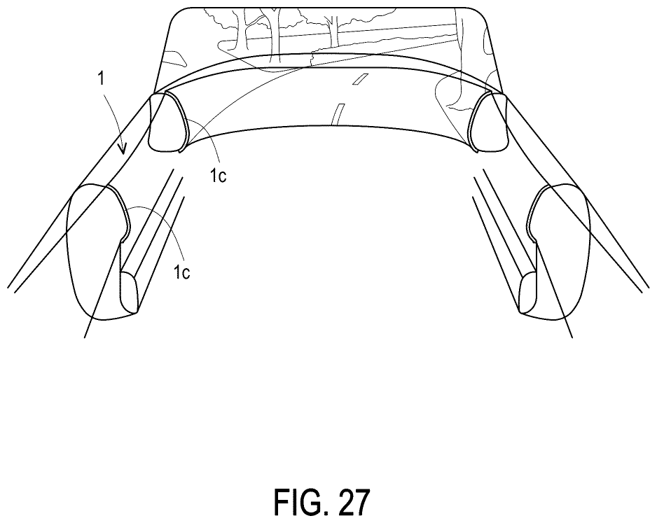

FIG. 27 is a schematic three-dimensional view of the curved display apparatus installed in the transportation vehicle according to an embodiment of the disclosure. Referring to FIG. 27, in some embodiments, the curved display apparatus 1 may be applied as a cabin display, and the shape curve 1c of the curved display apparatus 1 may be selectively the same at multiple locations inside the transportation vehicle, but the disclosure is not limited thereto.

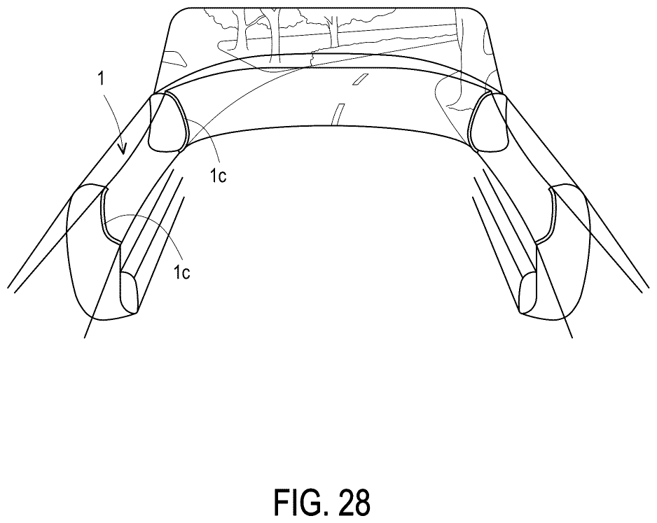

FIG. 28 is a schematic three-dimensional view of the curved display apparatus installed in the transportation vehicle according to an embodiment of the disclosure. Referring to FIG. 28, in some embodiments, the curved display apparatus 1 may be applied as a cabin display, and the shape curve 1c of the curved display apparatus 1 may be selectively different at multiple locations inside the transportation vehicle, but the disclosure is not limited thereto.

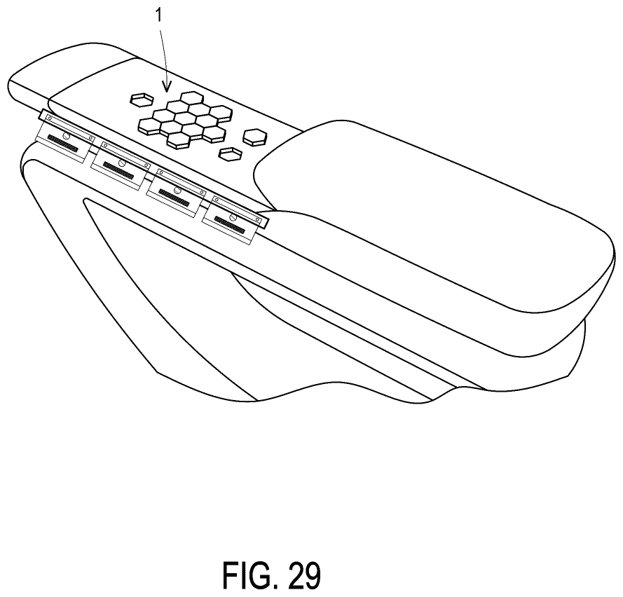

FIG. 29 is a schematic three-dimensional view of the curved display apparatus installed on an armrest according to an embodiment of the disclosure. Referring to FIG. 29, in some embodiments, the curved display apparatus 1 may be applied on an armrest inside a vehicle, but the disclosure is not limited thereto.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A curved display apparatus, comprising:
a curved carrier having a curved surface; and
a stretchable display module, comprising:
a stretchable display panel substantially arranged to fit on the curved surface of the curved carrier, wherein the stretchable display panel has a first edge and a second edge opposite to each other, and a length of the second edge is greater than a length of the first edge; and
a flexible electronic component, wherein the stretchable display panel has a bonding zone having the first edge of the stretchable display panel, the flexible electronic component is bonded to the bonding zone of the stretchable display panel, and the flexible electronic component has a fixation portion located outside the stretchable display panel; and
a first fixing member matched with the fixation portion of the flexible electronic component to fix the stretchable display module onto the curved carrier.

2. The curved display apparatus according to claim 1, wherein the stretchable display module further comprises:
a decorative component layer arranged on the stretchable display panel, wherein the first fixing member passes through the decorative component layer and the fixation portion of the flexible electronic component, and a portion of the first fixing member is arranged in the curved carrier.

3. The curved display apparatus according to claim 1, wherein the stretchable display module further comprises:
a decorative component layer arranged on the stretchable display panel;
an upper hard board layer embedded or buried in the decorative component layer and overlapping the bonding zone of the stretchable display panel;
a carrier board layer, wherein the stretchable display panel is arranged on the carrier board layer, and the stretchable display panel is located between the decorative component layer and the carrier board layer; and
a lower hard board layer, wherein the carrier board layer is located between the stretchable display panel and the lower hard board layer, and the lower hard board layer overlaps the bonding zone of the stretchable display panel,
the first fixing member passes through at least one of the upper hard board layer and the lower hard board layer.

4. The curved display apparatus according to claim 3, wherein the stretchable display module further comprises:
a sensing layer, wherein the carrier board layer is located between the stretchable display panel and the sensing layer, the sensing layer has a protrusion portion overlapping the lower hard board layer, the protrusion portion is engaged with the curved carrier, and the first fixing member further passes through the protrusion portion of the sensing layer.

5. The curved display apparatus according to claim 1, wherein the flexible electronic component includes a chip, and the first fixing member is located between the bonding zone of the stretchable display panel and the chip of the flexible electronic component.

6. The curved display apparatus according to claim 1, wherein the stretchable display module further comprises:
a decorative component layer arranged on the stretchable display panel, wherein the decorative component layer has a first extension portion crossing over the first edge of the stretchable display panel and extending outside the stretchable display panel,
the curved display apparatus further comprising:
a second fixing member connecting the first extension portion of the decorative component layer and the curved carrier.

7. The curved display apparatus according to claim 6, wherein the curved carrier further has a first surface connected to the curved surface, the first extension portion extends curvedly from above the stretchable display panel to the first surface of the curved carrier, and the second fixing member connects the first extension portion of the decorative component layer and the first surface of the curved carrier.

8. The curved display apparatus according to claim 7, wherein the second fixing member passes through the first extension portion of the decorative component layer and passes through or is inserted into the curved carrier.

9. The curved display apparatus according to claim 7, wherein the decorative component layer has a second extension portion crossing over the second edge of the stretchable display panel and extending outside the stretchable display panel, the curved display apparatus further comprising:
a third fixing member connecting the second extension portion of the decorative component layer and the curved carrier.

10. The curved display apparatus according to claim 9, wherein the curved carrier further has a second surface connected to the curved surface and is opposite to the first surface, the second extension portion extends curvedly from above the stretchable display panel to the second surface of the curved carrier, and the third fixing member connects the second extension portion of the decorative component layer and the second surface of the curved carrier.

11. A curved display apparatus, comprising:
a curved carrier having a curved surface; and
a stretchable display module, comprising:
a stretchable display panel substantially arranged to fit on the curved surface of the curved carrier, wherein the stretchable display panel has a first edge and a second edge opposite to each other, and
a flexible electronic component, wherein the stretchable display panel has a bonding zone having the first edge of the stretchable display panel, the flexible electronic component is bonded to the bonding zone of the stretchable display panel, and the flexible electronic component has a fixation portion located outside the stretchable display panel; and
a first fixing member matched with the fixation portion of the flexible electronic component to fix the stretchable display module onto the curved carrier.

12. The curved display apparatus according to claim 11, wherein the stretchable display module further comprises:
a decorative component layer arranged on the stretchable display panel, wherein the first fixing member passes through the decorative component layer and the fixation portion of the flexible electronic component, and a portion of the first fixing member is arranged in the curved carrier.

13. The curved display apparatus according to claim 11, wherein the stretchable display module further comprises:
a decorative component layer arranged on the stretchable display panel;
an upper hard board layer embedded or buried in the decorative component layer and overlapping the bonding zone of the stretchable display panel;
a carrier board layer, wherein the stretchable display panel is arranged on the carrier board layer, and the stretchable display panel is located between the decorative component layer and the carrier board layer; and
a lower hard board layer, wherein the carrier board layer is located between the stretchable display panel and the lower hard board layer, and the lower hard board layer overlaps the bonding zone of the stretchable display panel,
the first fixing member passes through at least one of the upper hard board layer and the lower hard board layer.

14. The curved display apparatus according to claim 13, wherein the stretchable display module further comprises:
a sensing layer, wherein the carrier board layer is located between the stretchable display panel and the sensing layer, the sensing layer has a protrusion portion overlapping the lower hard board layer, the protrusion portion is engaged with the curved carrier, and the first fixing member further passes through the protrusion portion of the sensing layer.

15. The curved display apparatus according to claim 11, wherein the flexible electronic component includes a chip, and the first fixing member is located between the bonding zone of the stretchable display panel and the chip of the flexible electronic component.
